(19) United States
(12) Patent Application Publication
(10) Pub. No.: US 2009/0108397 A1
(43) Pub. Date: Apr. 30, 2009

(54) THIN FILM DEVICE WITH LAYER ISOLATION STRUCTURE

(76) Inventors: Warren Jackson, Palo Alto, CA (US); Carl P. Taussig, Palo Alto, CA (US); Ping Mei, Palo Alto, CA (US); Albert Jeans, Palo Alto, CA (US); Han-Jun Kim, Pala Alto, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/932,653

(22) Filed: Oct. 31, 2007

(51) Int. Cl. H01L 29/00

(52) U.S. Cl. 257/529; 257/E29.001

(57) ABSTRACT

This invention provides a thin film device with layer isolation structures. Specifically, a plurality of patterned thin film device layers provide a first rail and a second rail. There is at least one overpass between the first rail and the second rail. The overpass is defined by an array of spaced holes disposed transversely through the continuous material of the first rail on either side of the overpass. The holes are in communication with isolation voids adjacent to the second rail adjacent to the overpass.

### FIELD

This invention relates generally to the field of imprint lithography and, in particular, to resulting thin film devices incorporating layer isolation structures.

### BACKGROUND

Socially and professionally, people in modem society rely more and more on electrical devices. Video displays in particular are increasingly common elements of professional and personal spaces appearing in cell phones, automated checkout lines, banking systems, PDAs, and of course displays for desktop and laptop computers and HDTV systems.

Especially for display devices, but also for other electronic devices, typically a plurality of thin film devices are incorporated into such devices. For displays, one or more transistors are commonly used to control the behavior of each pixel within the display. The individual nature of each pixel of an LED, plasma, electrophoretic, or LCD display introduces the possibility that each pixel may provide a different quantity of light. One pixel may be brighter or darker than another, a difference that may be quite apparent to the viewer. Circuit components such as logic gates and interconnects are typically used to control the transistors and or other components.

As a flat screen display may incorporate millions of thin film devices, great care is generally applied in the fabrication of LED, plasma and LCD displays in an attempt to ensure that the pixels and their controlling circuits are as uniform and consistently alike as is possible. Frequently, especially with large displays, quality control measures discard a high percentage of displays before they are fully assembled. As such, displays are generally more expensive than they otherwise might be, as the manufacturers must recoup the costs for resources, time and precise tooling for both the acceptable displays and the unacceptable displays.

Traditionally, thin film devices have been formed through processes such as photolithography. In a photolithographic process, a substrate is provided and at least one material layer is uniformly deposited upon the substrate. A photo-resist layer, also commonly known as a photoresist, or even simply a resist, is deposited upon the material layer, typically by a spin coating machine. A mask is then placed over the photoresist and light, typically ultra-violet (UV) light, is applied through the mask to expose portions of the photoresist. During the process of exposure, the photoresist undergoes a chemical reaction. Generally, the photoresist will react in one of two ways.

With a positive photoresist, UV light changes the chemical structure of the photoresist so that it is soluble in a developer. What “shows” therefore goes, and the mask provides a copy of the patterns which are to remain—such as, for example, the trace lines of a circuit. Photolithography may also be considered a 2D process, in that each layer of material is deposited and then masked. Although 3D structure may be created by stacking layers patterned via the 2D process, there is no inherent alignment feature between the layers.

A negative photoresist behaves in the opposite manner—the UV exposure causes it to polymerize and not dissolve in the presence of a developer. As such, the mask is a photographic negative of the pattern to be left. Following the developing with either a negative or positive photoresist, blocks of photoresist remain. These blocks may be used to protect portions of the original material layer, or serve as isolators or other components.

Very commonly, these blocks serve as templates during an etching process, wherein the exposed portions of the material layer are removed, such as, for example, to establish a plurality of conductive rows.

The morphology of the materials composing each material layer, and specifically the crystalline texture of each material at an interface between materials is often of significant importance to the operation of the thin film device. Surface defects and surface contaminants may negatively affect the interfaces between layers and possibly degrade the performance of the thin film device.

In addition, photolithography is a precise process applied to small substrates. In part this is due to the high cost of the photo masks. For the fabrication of larger devices, typically rather than employing a larger and even more costly photo mask, a smaller mask is repeatedly used—a process that requires precise alignment.

As a photolithographic process typically involves multiple applications of materials, repeated masking and etching, issues of alignment between the thin film layers is of high importance. A photolithographic process is not well suited for formation of thin film devices on flexible substrates, where expansion, contraction or compression of the substrate may result in significant misalignment between material layers, thereby leading to inoperable thin film devices. In addition a flexible substrate is not flat—it is difficult to hold flat during the exposure process and thickness and surface roughness typically can not be controlled as well as they can for glass or other non-flexible substrates.

The issue of flatness in photolithography can be problematic because the minimum feature size that can be produced by a given imaging system is proportional to the wavelength of the illumination divided by the numerical aperture of the imaging system. However the depth of field of the imaging system is proportional to the wavelength of the illumination divided by the square of the numerical aperture. Therefore as resolution is increased the flatness of the substrate quickly becomes the critical issue.

With respect to the flat screen displays introduced above, use of flexible substrates for the internal backplane controlling the pixels is often desired. Such a flexible substrate can provide a display with flexible characteristics and significant weight reduction for mobile applications. A flexible substrate may also be easier to handle during fabrication and provide a more mechanically robust display for the user.

In addition, many thin film devices involve components that rely on crossovers, as in one conductor crossing over another conductor, or the isolation of one or more internal layers from other layers. One type of fabrication method that has been advancing is roll-to-roll processing. Roll-to-roll processing provides continuous steady state processing with high throughput. In addition, as the imprinting template used to define the desired thin film structures is a continuous pattern provided by cylinder, in most instances roll-to-roll systems can be provided in smaller physical spaces, thereby permitting smaller clean room environments and reduced equipment costs. As roll-to-roll processing involves a flexible substrate, the alignment of features and establishing crossover isolation can be somewhat challenging.

Hence, there is a need for a thin film device that provides one or more isolation structures which can be fabricated using imprint lithography.

### SUMMARY

This invention provides a thin film device with isolation layer structure.

In particular, and by way of example only, according to an embodiment, provided is a thin film device with layer isolation structures including: a plurality of parallel thin film device layers, including at least a first layer and second layer patterned to define a first rail having a first dimension and a second rail; and at least one overpass between the first rail and the second rail, the overpass defined by an array of spaced holes disposed transversely through the continuous material of the first rail on either side of the overpass, each hole having a second dimension parallel to the first dimension, the holes in communication with isolation voids adjacent to the second rail adjacent to the overpass.

According to yet another embodiment, provided is a thin film device isolation structure including: a vertically aligned continuous crossover area between a first rail at a first level and a second rail at a second level, the first rail having a first dimension; a first group of first fuse chimneys disposed transversely through continuous material of the first rail adjacent to a first side of the crossover area, each first fuse chimney being in communication with a first isolation void adjacent to the crossover area of the second rail at the second level, each first fuse chimney having a second dimension parallel to the first dimension and positioned such that a predetermined amount of residual material remains disposed to either side of the fuse chimney in line with the second dimension; and a second group of second fuse chimneys disposed transversely through continuous material of the first rail adjacent to a second side of the crossover area, each second fuse chimney being in communication with a second isolation void opposite from the first isolation void and adjacent to the crossover area of the second rail, each second fuse chimney having a second dimension parallel to the first dimension and positioned such that a predetermined amount of residual material remains disposed to either side of the fuse chimney in line with the second dimension.

### BRIEF DESCRIPTION OF THE DRAWINGS

FIG. 1 is a perspective view of a thin film device with isolation structures in accordance with at least one embodiment;

FIG. 2 is a perspective view of an alternative thin film device with isolation structures in accordance with at least one embodiment;

FIG. 3 is a perspective view of the second layer occurring as the bottom layer of the thin film device with isolation structures shown in FIG. 1;

FIG. 4 is a perspective view of the second layer occurring as the bottom layer of the thin film device with isolation structures shown in FIG. 2;

FIG. 5 is a perspective view with partial cut through of the thin film device with isolation structures shown in FIG. 1;

FIG. 6 is a perspective view of a substrate with a plurality of thin film layers and 3D polymer as may be used in the formation of the thin film device with isolation structures shown in FIG. 1;

FIG. 7 is an enlarged section of FIG. 4; and

FIGS. 8-10 illustrate the method of etching and isolation provide by the isolation structures present in the thin film device with isolation structures shown in FIG. 1.

### DETAILED DESCRIPTION

Before proceeding with the detailed description, it is to be appreciated that the present teaching is by way of example, not by limitation. The concepts herein are not limited to use or application with a specific thin film device having isolation structures. Thus, although the instrumentalities described herein are, for the convenience of explanation, shown and described with respect to exemplary embodiments, it will be appreciated that the principles herein may be equally applied in other types of thin film device settings involving layer isolation.

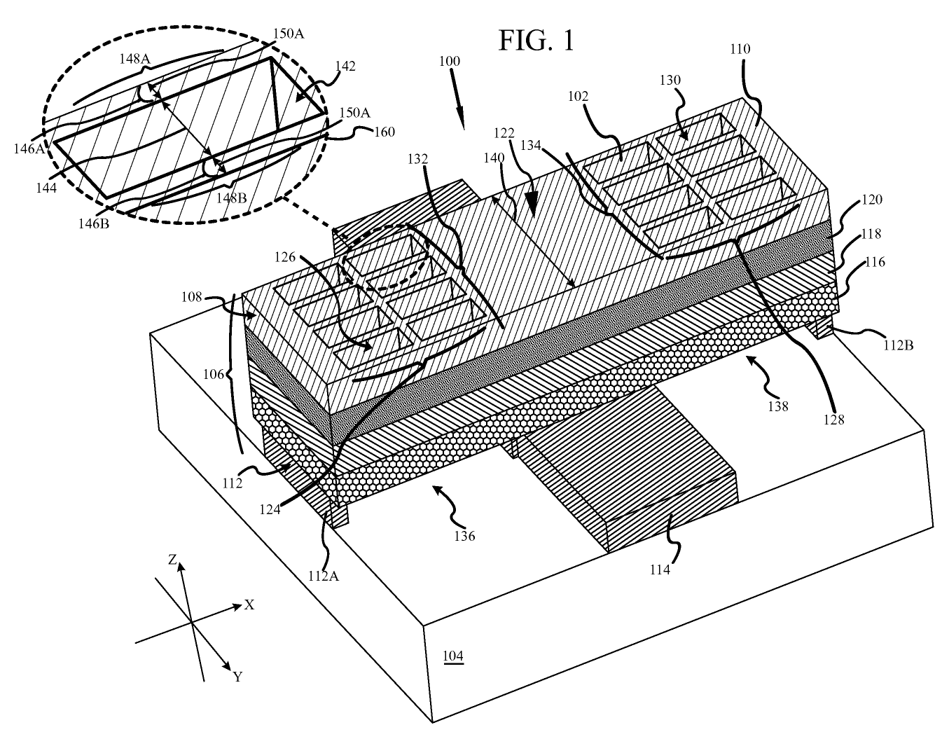

Turning now to the figures, and more specifically FIG. 1, there is shown a perspective view of an exemplary thin film device “TFD” 100 with layer isolation structures 102, upon a substrate 104. In at least one embodiment, the method for forming the TFD 100 incorporates Self-Aligned Imprint Lithography (“SAIL”), a recently developed technique for producing multilayer patterns on flexible substrates. The basics of this process are set forth and described in U.S. patent application Ser. No. 10/104,567, US Patent Publication Number 04-0002216, the disclosure of which is incorporated herein by reference.

As shown in FIG. 1, the TFD 100 has a plurality of thin film layers 106. A first layer 108 has been patterned to define a first rail 110. A second layer 112 has been patterned to define a second rail 114. As shown, in at least one embodiment the second rail 114 is transverse to the first rail 110.

In at least one embodiment the first layer 108 is a metal layer such that the first rail 110 is a first conductor. Similarly the second layer 112 is a metal layer such that the second rail 114 is a second conductor. As is further explained below, the material composition of the first layer 108 is understood to be different from the material composition of the second layer 112. In at least one example where the first and second layers are formed of metal, the metal material is selected from the group of chromium, molybdenum chromium, aluminum, titanium tungsten, and or combinations thereof. These two layers (108, 112) can be also made by other conductive materials such as indium tin oxide.

Typically, the TFD 100 has more than just two layers, e.g, first layer 108 and second layer 112, as the substrate may support a plurality of different thin film deices, and/or the TFD 100 itself may be part of a larger device. For the purposes of discussion herein, the illustrated layers between the first layer 108 and the second layer 112 are a dielectric layer 116, a channel semiconductor layer 118, and a contact layer 120. Dielectric layer 116 can be selected from the group of silicon nitride, silicon oxide, aluminum oxide, and or combinations thereof. Further still, semiconductor layer 118 can be selected from the group of amorphous or micro-crystalline Si, organic material, zinc oxide, and or combinations thereof.

Of course, it should be understood and appreciated that in varying embodiment, different thin film layers may be provided, and in greater or lesser numbers. Indeed, where the TFD is intended to be a simple electrical crossover, at least one isolation layer is understood to be between the first and second layers (108, 112) and other layers may or may not be provided.

As shown in FIG. 1, there is a continuous crossover area 122 between the first rail 110 and the second rail 114. In at least one context, the crossover area 122 may be considered as an overpass between the first rail 110 and the second rail 114. Moreover, it is understood and appreciated that the first rail 110 is passing over, e.g., crossing over, the second rail 114 without electrical contact there between. Further still, in at least one embodiment, the crossover area 122 is a vertically aligned crossover area 122, wherein the first and second rails remain in respective and continuous parallel planes. Moreover, in at least one embodiment, the crossover area 122 need not be rectangular as shown but rather any arbitrary shape.

As shown, the crossover area 122 is bounded by a first group 124 of fuse chimneys, of which first fuse chimney 126 is exemplary, and a second group 128 of fuse chimneys of which second fuse chimney 130 is exemplary. The first group 124 is disposed adjacent to the first side 132 of the crossover area 122. The second group 128 is disposed adjacent to the second side 134 of the crossover area 122.

More specifically, each first and second fuse chimney is disposed transversely through the continuous material of the first rail 110. Each first fuse chimney 126 continues through any subsequent layers and is in communication with a first isolation void 136 adjacent to the crossover area of the second rail 114. Moreover, as shown there is a physical void providing physical separation between the second rail 114 portion of second layer 112 and second layer remnant 112A, which may be another conductor provided by second layer 112 and otherwise unrelated to the crossover 122.

Each second fuse chimney 130 continues through any subsequent layers and is in communication with a second isolation void 138 opposite from the first isolation void 136 and adjacent to the crossover area of the second rail 114. Moreover, as shown there is a physical void providing physical separation between the second rail 114 portion of second layer 112 and second layer remnant 112B, which may be yet another conductor provided by the second layer 112 and otherwise unrelated to the crossover 122.

First rail 110 has a first dimension 140, which may in at least one embodiment be termed a width. In at least one alternative embodiment, one or more first fuse chimneys 126 and second fuse chimneys 130 are different. Further, in at least one embodiment each first fuse chimney 126 and second fuse chimney 130 is substantially identical. For ease of illustration and discussion, it is assumed that with respect to exemplary TFD 100 the first and second fuse chimneys are substantially identical.

As shown in the enlarged area of dotted circle 160, enlarged representative fuse chimney 142 has a second dimension 144 which may also be termed a width. This second dimension 144 is parallel to the first dimension 140. Further the disposition of representative fuse chimney 142 is such that a predetermined amount of residual material 146, e.g., 146A, 146B, remains disposed to either side of representative fuse chimney 142 in line with the second dimension 144. Although shown as an enlargement of a member of the first group 124 of first fuse chimneys 126, it is understood and appreciated that the representative fuse chimney 142, is in at least one embodiment, a representative of fuse chimneys from either the first or second groups (124, 128).

In at least one embodiment the residual material 146 may be further identified as fuse areas 148, e.g., 148A, 148B, of the fuse chimney 142. In at least one embodiment, the fuse areas 148 are generally angled, e.g., transverse, to the first dimension 140. Indeed, it is not required that the fuse areas 148 be perpendicular to the first dimension 140. With respect to FIG. 1, it is also appreciated that in at least one embodiment, adjacent fuse chimneys may share a common fuse area 148 between them.

The fuse areas 148 have a third dimension 150, e.g., third dimension 150A, 150B, that is less than the first dimension 140. In other words, the each fuse chimney of the first group 124 and the second group 128 displaces physical material in first rail 110, such that although the overall width of first rail 110 is shown as about equal to the first dimension 140 of the crossover area 122, there is less physical material in the area of first rail 110 in which first group 124 and second group 128 of fuse chimneys are disposed. Where, as in exemplary first group 124 and second group 128 multiple rows of fuse chimneys are provided, the end to end spacing is also understood and appreciated to be about the same as the third dimension 150.

Moreover, the fuse area 148 portions of the first rail 110, and any subsequent layers, are much narrower in areas vertically above an isolation void, e.g. isolation void 136, then is the width, e.g. first dimension 140, of the first rail 110 and any subsequent layers where an isolation void is not provided. In at least one embodiment, the third dimension is about between 1 and 6 μm whereas other non-fuse area portions of the TFD 100 are at least 2-3 μm wider.

The fuse chimneys, e.g. representative fuse chimney 142, are in essence holes 142 that pass vertically through the first rail 110 and any subsequent layers of material to arrive in eventual communication with the first and second isolation voids 136, 138 as described above. They have been termed fuse chimneys for the purposes of this description to assist in understanding and appreciating their structural function during TFD 100 fabrication. These fuse chimneys, as holes, communicate etchant to the second layer to for the formation of the first and second isolation voids 136, 138.

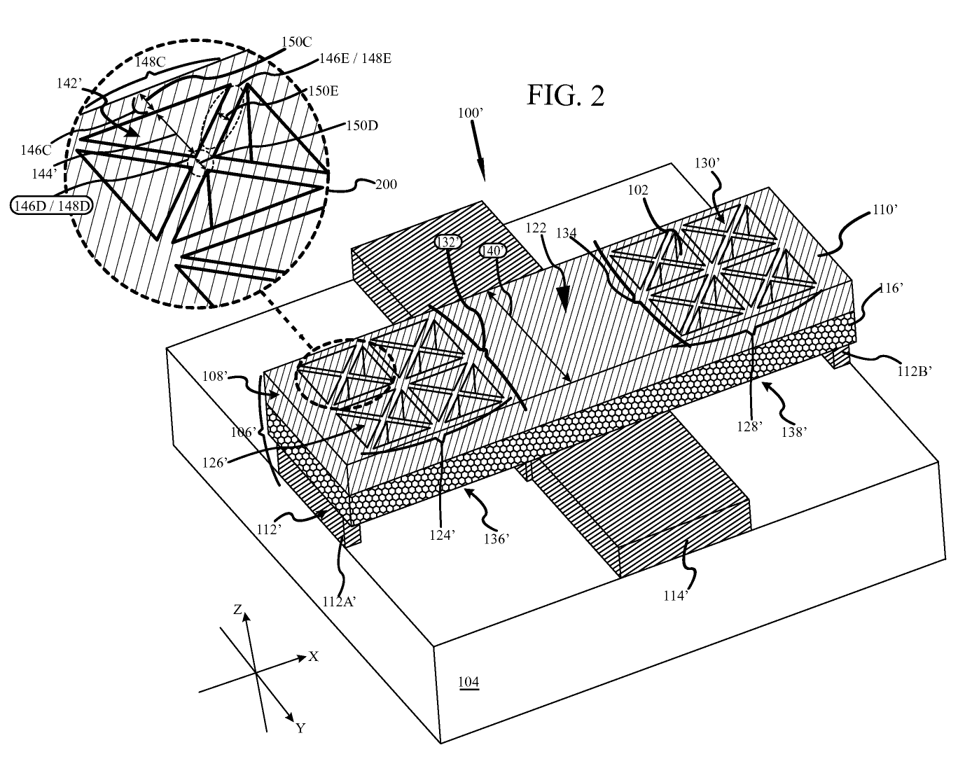

It is also understood that although the representative fuse chimney 142 is shown to be rectangular in cross section, the geometry of the fuse chimney in cross section may be round, square, triangular, oval, or other closed geometric form. An alternative TFD 100′ is shown in FIG. 2 wherein the fuse chimneys have been rendered with a triangular cross section. In addition, FIG. 2 illustrates a more simplified TFD 100′ as between the first layer 108 and the second layer 112 there is only a dielectric layer 116′ shown. As shown in the enlarged area of dotted circle 200, representative fuse chimney 142′ is again shown to have a second dimension 144′ that is parallel to the first dimension 140′. Further there is residual material 146C and 146D disposed to either side of representative fuse chimney 142′ in line with the second dimension 144′.

As in FIG. 1, this residual material may be further identified as fuse areas 148C, 148D. Again, the fuse areas 148 have a third dimension 150, e.g., third dimension 150C, 150D, that is less than the first dimension 140′. As the fuse chimneys of FIG. 2 are shown to be triangular, the residual material 146E, e.g., fuse area 148E is also angled, and also has third dimension 140E.

With respect to FIG. 1 and 2, although a single fuse chimney might suffice, the application of a plurality of first fuse chimneys 126 in the first group 124 and a plurality of second fuse chimneys 130 in the second group 128 is advantageous. The number of fuse chimneys in the first group 124 and the second group 128, and the third dimension 150 of the fuse areas 148 is specifically selected to achieve two conditions.

First, the fuse areas 148 of first rail 110 have collectively sufficient width 150A to provide adequate electrical conductivity (where first rail 110 is conductive) without significant impedance. Second, and as is further discussed below, the fuse areas 148 established in the second layer 112 each have dimensions 150A sufficiently small to etch through quickly and effectively disappear all together before wider areas of the second layer 112 are adversely affected. Moreover, the fuse areas 148 established in each layer through which each fuse chimney 142 passes are susceptible to different etchants, such that removal of the of fuse areas 148 present in the second layer 112 is advantageously accomplished without adverse removal of fuse areas 148 present in other, non-selected areas.

Moreover, the design criterion here is to insure that the cross section of the undercut regions can conduct the required current while being sufficient thin to undercut. An array of undercut regions enables larger currents to be passed while maintaining isolation between second rail 114 and second layer remnants 112A and 112B. It should be mentioned that in other embodiments, the fuse chimneys and isolation voids can used to maintain heat conduction or mechanical force transmission in the upper layer while insuring isolation of various regions in the lower layers.

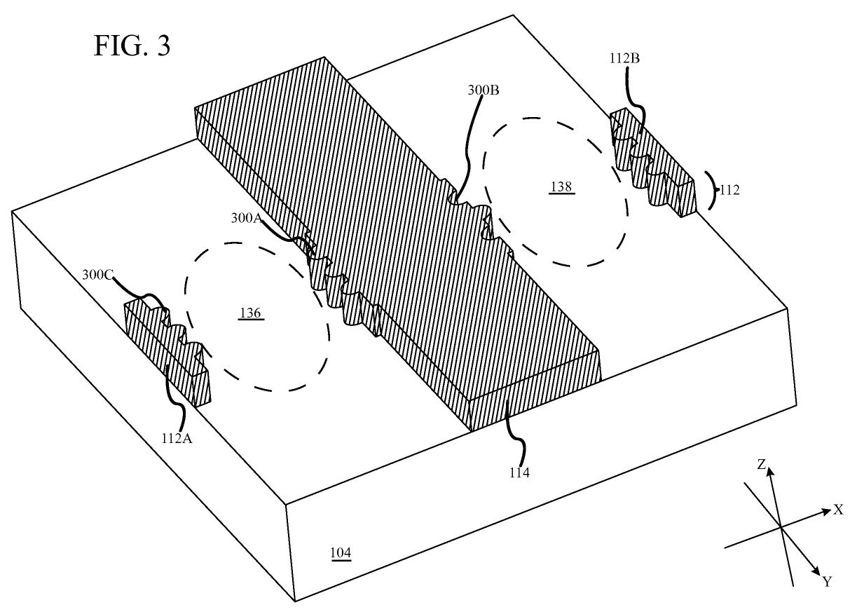

The first isolation void 136 and second isolation void 138 are more clearly shown in FIG. 3, which depicts only the second layer 112 of the TFD 100 of FIG. 1 in patterned form. More specifically second rail 114 is clearly appreciated to be physically separate from remnant 112A and remnant 112B. With respect to FIG. 3, it is also apparent that in at least one embodiment at least one fuse vestige 300 remains proximate to the location of at least one fuse chimney. More specifically, the fuse vestige 300 is typically a portion of a fuse area of the etchant susceptible layer (e.g., second layer 112) that was not completely etched away during fabrication of TFD 100.

The one or more fuse vestiges may be connected to the second rail 114 and/or to one or both remnants 112A, 112B. In at least one embodiment the second rail 114 has at least one fuse vestige. This fuse vestige may protrude from the second rail 114 as fuse vestige 300A, or may cavity into the second rail 114 as fuse vestige 300B. Second layer remnant 112A and or 112B may also have one or more fuse vestiges, such as fuse vestige 400.

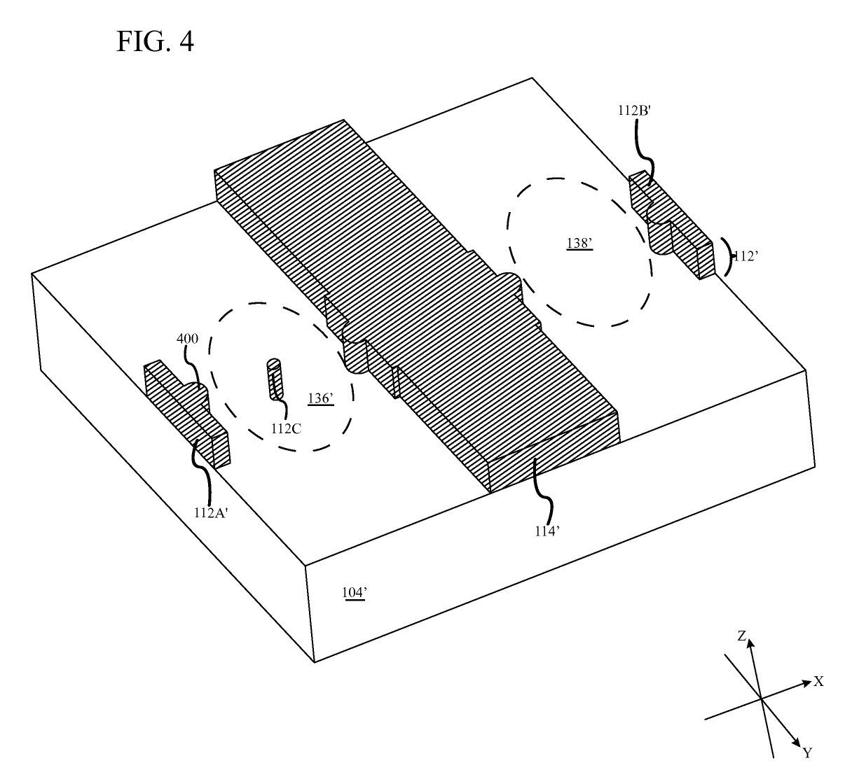

With respect to the TFD 100′ of FIG. 2, the first isolation void 136 and second isolation void 138 of TFD 100′ are more clearly shown in FIG. 4. As in FIG. 3, it is clearly appreciated that second rail 114′ is physically separated from remnant 112A′ and remnant 112B′. As the geometric patter of the fuse chimneys in the first and second groups 124′, 126′ it is possible that a remnant 112C may exist. As shown, remnant 112C is at best a support structure and in no way serves to connect the second rail 114′ with remnant 112A′.

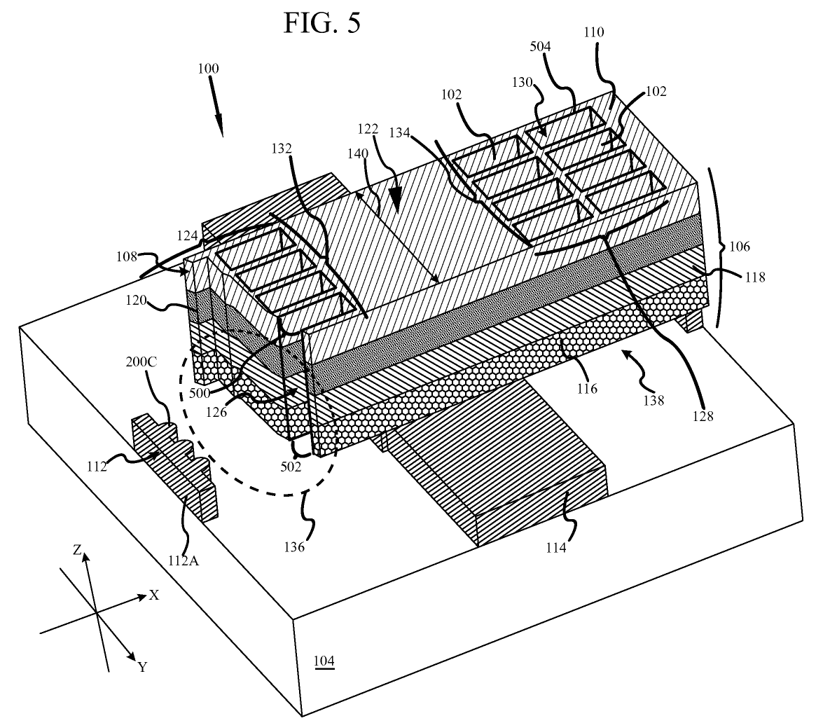

FIG. 5 provides a partial cut away of the TFD 100 in FIG. 1. As shown, first fuse chimney 126 is more fully appreciated to have a first top aperture 500 and a first bottom aperture 502, the first bottom aperture 502 being in communication with the first isolation void 136. Each second fuse chimney 130 likewise has a second top aperture 504 and a second bottom aperture, not shown, in communication with the second isolation void 138.

In FIG. 5 the one or more fuse vestiges on the second rail 114 are not visible, however fuse vestiges, such as fuse vestige 300C is clearly visible upon second layer remnant 112A

Moreover, with respect to FIGS. 1 and 3, in exemplary TFD 100 at least one continuous overpass 122 exists between the first rail 110 and the second rail 114. This overpass 122 is defined by an array of spaced holes (e.g., first and second fuse chimneys 126, 130) disposed transversely through the continuous material of the first rail on either side of the overpass 122.

With respect to FIGS. 1 and 5, it is further appreciated that in at least one embodiment the second rail 112 is inset slightly from the vertical shadow provided by the first rail 110 and any other intervening layers, such as 116, 118 and 120, as shown. More specifically, when the etching process is performed with the selected etchant to remove the fuse areas 148 initially present in the second layer 112 and thereby achieve the first isolation void 136 and the second isolation void 138, other areas of second layer 112 are also slightly over etched. Because of the relative thickness of the fuse areas 148 being substantially smaller then the width of the intended second rail 114, this additional loss of material is substantially negligible. However, the slightly reduced width results in a slight inset which is plainly visible upon inspection, especially in areas proximate to the crossover area 122.

As shown in FIGS. 1 and 5, the first rail 110 is generally running as a continual straight conductor across the overpass 120. In at least one embodiment, the first group 124 or the second group 128 of fuse chimneys may be offset from each other such that the crossover is a zig-zag. In addition, either the first side 132 or the second side 134 may have a plurality of first rails 110 extending there from.

Further, although in the accompanying figure illustrations the first rail 110 is shown to be the top layer and the second rail 114 is shown to be the bottom layer, this depiction is not a limitation. Indeed the subsequent layers may be disposed above the first rail 110 and the second rail 114 may exist within the structure at locations other than the bottom layer. In addition, there may be multiple instances of the first rail 110 at different vertical heights and/or multiple instances of the second rail 114 at different vertical heights.

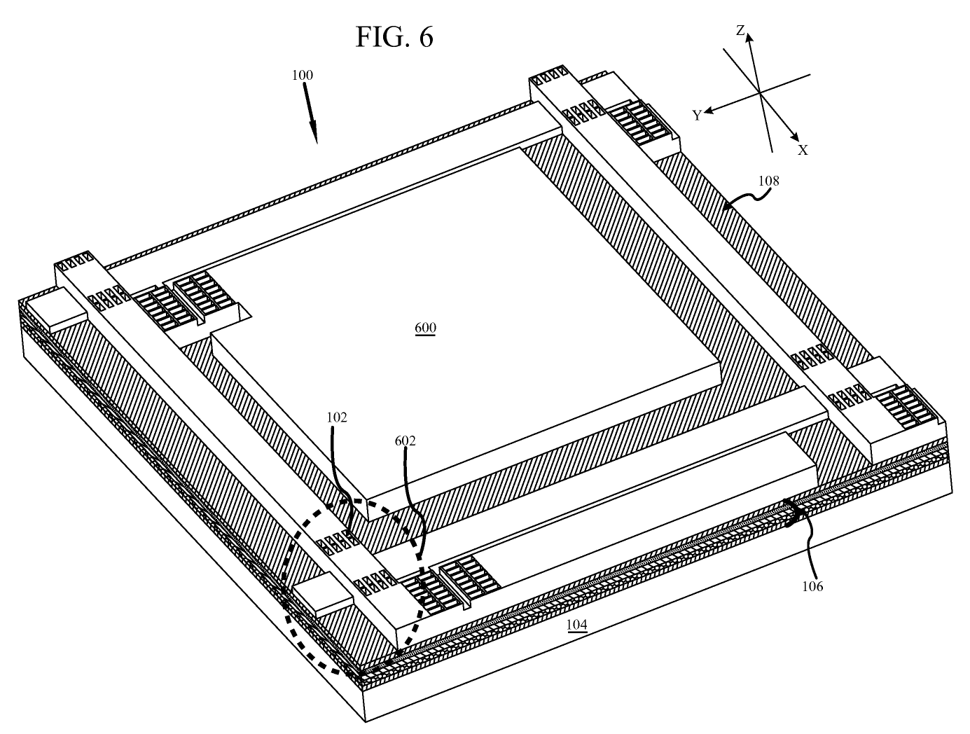

As stated, the fuse chimneys are isolation structures 102 utilized during device fabrication to communicate etchant to the second layer 112 to form the first and second isolation voids 136, 138. This process is more fully set forth in FIGS. 6-10.

Turning to FIG. 6, provided is a portion of a substrate 104. Typically the substrate 104 is chemically cleaned to remove any particulate matter, organic, ionic, and/or metallic impurities or debris that may be present upon the surface of the substrate 104. A plurality of thin film layers 106 is disposed upon the substrate as a stack, the stack having a first layer 108 and a second layer 112. It is appreciated that these applied as a stack are substantially parallel with respect to each other, and unless a duplicate layer of material is reapplied in the stack, the material of one layer remains within that specific layer and does not cross through one or more adjacent layers above or below.

In accordance with the SAIL technique identified above, a 3D patterned resist 600 is provided upon the stack of thin film layers 106. The SAIL technique is advantageous in roll-to-roll processing as the 3D resist 600 is flexible permitting the 3D resist 600, and more specifically the pattern of the 3D resist 600, to stretch or distort to the same degree as the substrate. As such, a SAIL roll-to-roll fabrication process may be employed to provide low cost manufacturing solutions for devices such as flat and/or flexible displays, or other devices suitable for roll-to-roll processing. Of course, the SAIL process and method of forming the TDF with isolation structures may also be performed upon a non-flexible substrate 104.

In at least one embodiment, a polymer such as an imprint polymer or imprint resist, is deposited upon the stacked thin film layers 106 and imprinted by a stamping tool. The resist or polymer may comprise any of a variety of commercially available polymers. For example, a polymer from the Norland optical adhesives (NOA) family of polymers could be used. A silicone material may also be used as is described in patent application Ser. No. 10/641,213 entitled “A Silicone Elastomer Material for High-Resolution Lithography” which is herein incorporated by reference.

A method for utilizing a stamping tool to generate a 3D Structure in a layer of material is described in patent application Ser. No. 10/184,587 entitled “A Method and System for Forming a Semiconductor Device” which is herein incorporated by reference. A stamping tool is further described in patent application Ser. No. 10/103,300 entitled “Imprint Stamp” which is herein incorporated by reference. With further respect to roll-to-roll processing where substrate 104 may be of arbitrary size, yet another method for providing a 3D Structure is described in U.S. Pat. No. 6,808,646 entitled “Method of Replicating a High Resolution Three-Dimension Imprint Pattern on a Compliant Media of Arbitrary Size” which is also herein incorporated by reference.

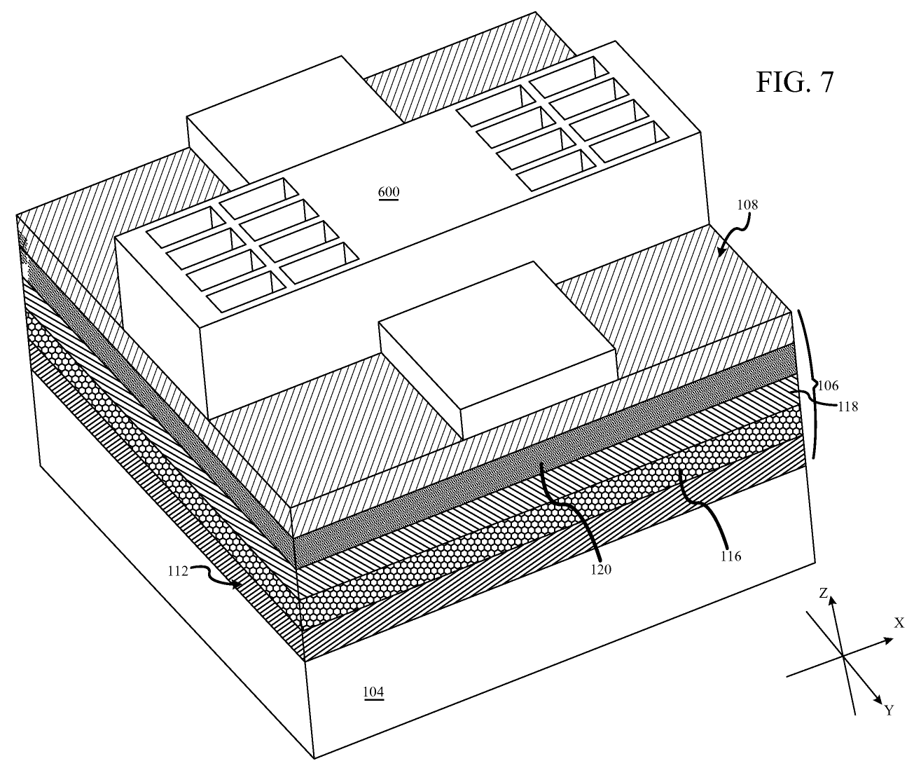

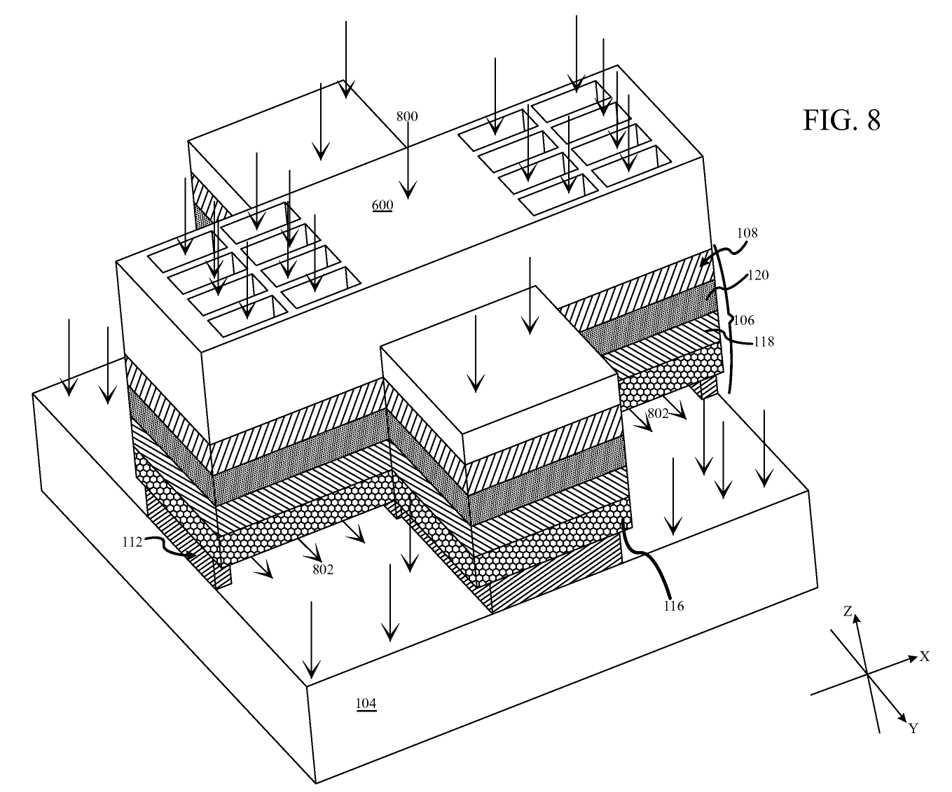

The area bounded by dotted circle 602 corresponds to the eventual TFD 100 shown in FIGS. 1, 3 and 5, and is enlarged in FIG. 7. FIG. 8 illustrates the process of etching, specifically ion etching. The etching process may involved a series of etches, first to remove any residual polymer, then the exposed portions of the first layer 108, then subsequently exposed portions of the contact layer 120, the semiconductor layer 118, the dielectric layer 116 and the second layer 112.

Preferably in at least one embodiment these etches are substantially anisotropic as illustrated by arrows 800 being substantially perpendicular to substrate 104. The first group 124 of fuse chimneys and the second group 128 of fuse chimneys permit the etching process to be performed on specifically localized sections of the thin film layers 106 that are otherwise covered by the 3D resist 600. In general these etches are mutually selective. Further, it is understood that generally a layer is completely removed before etching on the layer beneath is commenced.

It is generally understood that an ion etching process may be accomplished by either of two traditional processes—a physical process or an assisted physical process. In a physical etching environment, no chemical agent is provided. Rather, the removal of material is entirely dependent upon the physical impact of the ions knocking atoms off the material surface by physical force alone. Physical ion etching is commonly referred to as ion milling or ion beam etching. Physical ion etching is also typically referred to as a dry process. A physical etching process is typically very anisotropic.

In an assisted physical process such as a reactive ion etching process, or RIE, removal of material comes as a combined result of chemical reactions and physical impact. Generally, the ions are accelerated by a voltage applied in a vacuum. The effect of their impact is aided by the introduction of a chemical which reacts with the surface being etched. In other words, the reaction attacks and removes the exposed surface layers of the material being etched.

An RIE process advantageously permits very accurate etching of the one or more layers with little appreciable effect upon other layers. In other words, specific selection of different materials permits an RIE process to soften one layer without significantly softening another. In at least one embodiment, the removal or etching of the plurality of thin film layers 106 is accomplished with RIE. Although ion etching and RIE have been described in conjunction with at least one embodiment, it is understood and appreciated that one of ordinary skill in the art will recognize that a variety of different etch processes could be utilized without departing from the scope and spirit herein disclosed.

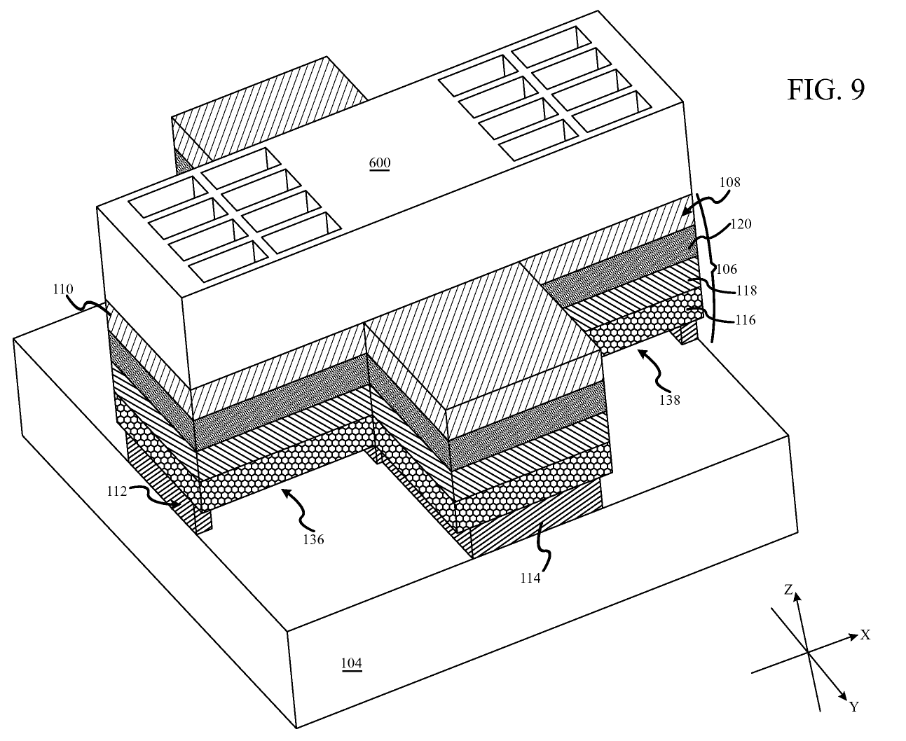

When etching is performed upon the second layer 110, the process, though generally anisotropic, is continued for a sufficient period so as to burn through, dissolve, eat, or otherwise remove the fuse areas 148 of the fuse chimneys portion initially present in the second layer. This results in partial isotropic etching as indicated by arrows 802. This isotropic etching is sufficient to remove the fuse areas 148 and provide isolation areas 136, 138 and only minimally undercuts the normal portions of second layer 112, for the resulting structure shown in FIG. 9.

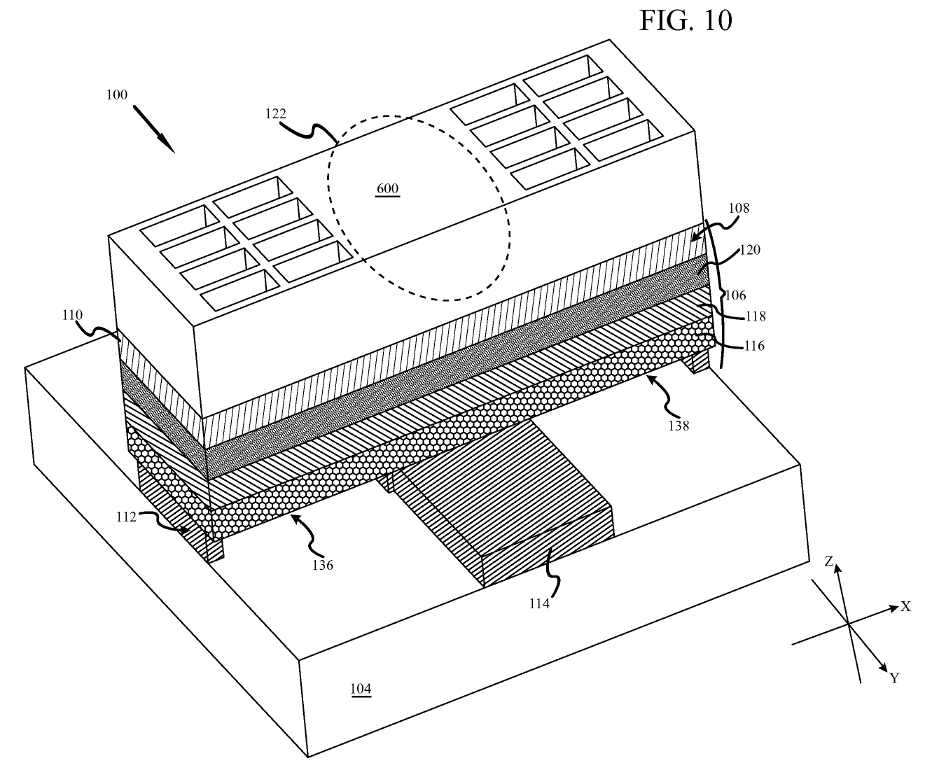

Further etching is then performed to reduce the height of the 3D polymer 600 and expose portions of the first layer 108, see FIG. 9. Selective etching is then performed to further define the first rail 110 and the second rail 112 as shown in FIG. 10. The crossover area 122 is now established as well. Removing the remaining portion of the 3D polymer 600 from the developing structure in FIG. 10 results in TFD 100 as shown and described with respect to FIGS. 1, 3 and 5 above.

Changes may be made in the above methods, systems, processes and structures without departing from the scope hereof. It should thus be noted that the matter contained in the above description and/or shown in the accompanying drawings should be interpreted as illustrative and not in a limiting sense. The following claims are intended to cover all generic and specific features described herein, as well as all statements of the scope of the present method, system and structure, which, as a matter of language, might be said to fall therebetween.

What is claimed is:

1. A thin film device with layer isolation structures comprising:
a plurality of parallel thin film device layers, including at least a first layer and second layer patterned to define a first rail having a first dimension and a second rail; and
at least one overpass between the first rail and the second rail, the overpass defined by an array of spaced holes disposed transversely through the continuous material of the first rail on either side of the overpass, each hole having a second dimension parallel to the first dimension, the holes in communication with isolation voids adjacent to the second rail adjacent to the overpass.

2. The thin film device of claim 1, further including at least one isolation layer between the first layer and the second layer.

3. The thin film device of claim 1, wherein each hole has fuse areas transverse to the first dimension, the fuse areas having a third dimension less than the first dimension.

4. The thin film device of claim 1, wherein the isolation void extends through more than one layer.

5. The thin film device of claim 1, wherein each hole is a fuse chimney.

6. The thin film device of claim 1, wherein the first rail is a first conductor and the second rail is a second conductor.

7. The thin film device of claim 1, wherein the second rail has at least one fuse vestige proximate to at least one hole.

8. The thin film device of claim 1, wherein the second rail is inset from the vertical shadow of the first rail.

9. The thin film device of claim 1, wherein the holes are arrayed to isolate one part fo the second layer from another part of the second layer.

10. A thin film device with layer isolation structures comprising:
a plurality of thin film device layers, including at least a first layer providing a first rail and a second layer providing a second rail;
at least one crossover area between the first rail and the second rail;
a first group of first fuse chimneys disposed transversely through continuous material of the first rail adjacent to a first side of the crossover area, each first fuse chimney having a first top aperture and a first bottom aperture, the first bottom aperture being in communication with a first isolation void adjacent to the crossover area of the second rail; and
a second group of second fuse chimneys disposed transversely through continuous material of the first rail adjacent to a second side of the crossover area, each second fuse chimney having a second top aperture and a second bottom aperture, the second bottom aperture being in communication with a second isolation void opposite from the first isolation void and adjacent to the crossover area of the second rail.

11. The thin film device of claim 10, wherein the first rail is a first conductor and the second rail is a second conductor.

12. The thin film device of claim 10, wherein the second rail has at least one fuse vestige proximate to at least one fuse chimney.

13. The thin film device of claim 10, wherein the second rail is inset from the vertical shadow of the first rail.

14. The thin film device of claim 10, wherein the at least one first group and second group of fuse chimneys are arrayed to isolate one part of the second layer from another part of the second layer.

15. The thin film device of claim 10, wherein the isolation void extends through more than one layer.

16. The thin film device of claim 10, further including at least one isolation layer between the first layer and the second layer.

17. The thin film device of claim 10, wherein the thin film device layers are parallel.

18. The thin film device of claim 10, wherein the first rail has a first dimension, each fuse chimney having fuse areas transverse to the first dimension, the fuse areas having a third dimension less than the first dimension.

19. A thin film device isolation structure comprising:
a vertically aligned continuous crossover area between a first rail at a first level and a second rail at a second level, the first rail having a first dimension;
a first group of first fuse chimneys disposed transversely through continuous material of the first rail adjacent to a first side of the crossover area, each first fuse chimney being in communication with a first isolation void adjacent to the crossover area of the second rail at the second level, each first fuse chimney having a second dimension parallel to the first dimension and positioned such that a predetermined amount of residual material remains disposed to either side of the fuse chimney in line with the second dimension; and
a second group of second fuse chimneys disposed transversely through continuous material of the first rail adjacent to a second side of the crossover area, each second fuse chimney being in communication with a second isolation void opposite from the first isolation void and adjacent to the crossover area of the second rail, each second fuse chimney having a second dimension parallel to the first dimension and positioned such that a predetermined amount of residual material remains disposed to either side of the fuse chimney in line with the second dimension.

20. The thin film isolation structure of claim 19, wherein the first and second groups of fuse chimneys are arrayed to isolate one part of the second layer from another part of the second layer.

21. The thin film isolation structure of claim 19, wherein the second rail has at least one fuse vestige proximate to at least one fuse chimney.

22. The thin film device of claim 19, wherein the second rail is inset from the vertical shadow of the first rail.

23. The thin film isolation structure of claim 19, further including at least one isolation layer between the first layer and the second layer.

24. The thin film isolation structure of claim 19, wherein the first rail is a first conductor and the second rail is a second conductor.

25. The thin film isolation structure of claim 19, wherein the isolation void extends through more than one layer.
